(19) United States
(12) Patent Application Publication
(10) Pub. No.: US 2026/0190552 A1
(43) Pub. Date: Jul. 2, 2026

(54) SEMICONDUCTOR DEVICE

(71) Applicant: EPISTAR CORPORATION, Hsinchu (TW)

(72) Inventors: Jih-Kang CHEN, Hsinchu (TW); Po-Wen HSIAO, Hsinchu (TW)

(21) Appl. No.: 19/436,688

(22) Filed: Dec. 30, 2025

(30) Foreign Application Priority Data
Dec. 31, 2024 (TW) 113151703

(51) Int. Cl. H10H 20/841; H10H 20/831

(52) U.S. Cl. CPC H10H 20/841; H10H 20/831

(57) ABSTRACT

The present disclosure provides a semiconductor device including an epitaxial structure, a first pad, a first contact electrode and a first barrier structure. The epitaxial structure includes a first semiconductor structure, a second semiconductor structure, and an active structure located between the first semiconductor structure and the second semiconductor structure. The first pad is located on the second semiconductor structure. The first contact electrode is located between the second semiconductor structure and the first pad. The first barrier structure is located between the first contact electrode and the first pad and includes a first metal layer and a second metal layer. The first metal layer has a first reflectivity for a light with a wavelength ranging from 950 nm to 1200 nm, and the second metal layer has a second reflectivity for the light with the wavelength ranging from 950 nm to 1200 nm, and the second reflectivity is larger than the first reflectivity. The first metal layer includes a first thickness, the second metal layer includes a second thickness, and the first thickness is larger than the second thickness.

### RELATED APPLICATION

This application claims the benefit of priority to Taiwanese Application Serial No. 113151703, field Dec. 31, 2024, “Semiconductor Device,” the contents of which is incorporated herein by reference in its entirety.

### TECHNICAL FIELD

The present disclosure relates to a semiconductor device, and particularly relates to a micro semiconductor device for optoelectronics.

### CROSS REFERENCE TO RELATED APPLICATION

This application claims the right of priority based on TW Application Serial No. 113151703, filed on Dec. 31, 2024, and the content of which is hereby incorporated by reference in its entirety.

### DESCRIPTION OF BACKGROUND ART

Semiconductor devices have a wide range of applications, and research and development of related materials and products have continued in recent years. For example, III-V group semiconductor materials, which include group III and group V elements, can be applied to various semiconductor devices for optoelectronics, such as light-emitting diodes (LEDs), laser diodes (LDs), photodetectors, solar cells, or power devices (e.g. switching devices or rectifiers), and thus can be widely used in fields including lighting, medical care, display, communication, sensing, and power system. Among them, LEDs, as a type of the semiconductor devices, have advantages, such as low power consumption, fast response, small size, and long lifespan, and are widely used in various fields.

### SUMMARY OF THE DISCLOSURE

One embodiment of the present disclosure provides a semiconductor device. The semiconductor device includes an epitaxial structure, a first pad, a first contact electrode and a first barrier structure. The epitaxial structure includes a first semiconductor structure, a second semiconductor structure, and an active structure located between the first semiconductor structure and the second semiconductor structure. The first pad is located on the second semiconductor structure. The first contact electrode is located between the second semiconductor structure and the first pad. The first barrier structure is located between the first contact electrode and the first pad and includes a first metal layer and a second metal layer. The first metal layer has a first reflectivity for a light with a wavelength ranging from 950 nm to 1200 nm, the second metal layer has a second reflectivity for the light with the wavelength ranging from 950 nm to 1200 nm, and the second reflectivity is larger than the first reflectivity. The first metal layer includes a first thickness, the second metal layer includes a second thickness, and the first thickness is larger than the second thickness.

### BRIEF DESCRIPTION OF THE DRAWINGS

FIG. 1A shows a schematic top view of a semiconductor device in accordance with some embodiments of the present disclosure.

FIG. 1B shows a schematic sectional view of the semiconductor device shown in FIG. 1A taken along line A-A′.

FIG. 1C shows a schematic enlarged view of the region B shown in FIG. 1B.

FIG. 2A shows a schematic top view of a semiconductor device in accordance with other embodiments of the present disclosure.

FIG. 2B shows a schematic sectional view of the semiconductor device shown in FIG. 2A taken along line B-B′.

FIG. 3A shows a schematic top view of a display in accordance with some embodiments of the present disclosure.

FIG. 3B shows a schematic sectional view of a display in accordance with some embodiments of the present disclosure.

FIG. 3C shows a schematic sectional view of a display in accordance with other embodiments of the present disclosure.

### DETAILED DESCRIPTION OF PREFERRED EMBODIMENTS

The embodiments of the present disclosure will be described in detail below with reference to the drawings so that those skilled in the art can fully understand the spirit of the present disclosure. It should be noticed that the embodiments for showing the semiconductor device in the present invention are not intended to limit the present invention to these embodiments. In the drawings or the specification, some identical symbols indicate devices having the same or similar structure, function, or principle. Unless otherwise specified, the shapes or dimensions of the elements in the drawings are for illustrative purposes only and are not intended to limit the actual scope. It should be particularly noticed that components not shown or described in the drawings may be implemented in forms known to those skilled in the art.

Unless otherwise specified, the general formula InGaP may represent Inₓ₀Ga₁₋ₓ₀P, in which 0<x0<1; the general formula AlInP may represent Alₓ₁In₁₋ₓ₁P, in which 0<x1<1; the general formula InGaN may represent Inₓ₂Ga₁₋ₓ₂N, in which 0<x2<1; the general formula AlGaN may represent Alₓ₃Ga₁₋ₓ₃N, in which 0<x3<1; the general formula AlGaInP may represent Alₓ₄Gaₓ₅In₁₋ₓ₄₋ₓ₅P, in which 0<x4<1 and 0<x5<1; the general formula InGaAsP may represent Inₓ₆Ga₁₋ₓ₆Asₓ₇P₁₋ₓ₇, in which 0<x6<1 and 0<x7<1; the general formula AlGaInAs may represent Alₓ₈Gaₓ₉In₁₋ₓ₈₋ₓ₉As, in which 0<x8<1 and 0<x9<1; the general formula InGaNAs may represent Inₓ₁₀Ga₁₋ₓ₁₀Nₓ₁₁As₁₋ₓ₁₁, in which 0<x10<1 and 0<x11<1; the general formula InGaAs may represent Inₓ₁₂Ga₁₋ₓ₁₂As, in which 0<x12<1; the general formula AlGaAs may represent Alₓ₁₃Ga₁₋ₓ₁₃As, in which 0<x13<1; and the general formula AlInGaN may represent Alₓ₁₄Inₓ₁₅Ga₁₋ₓ₁₄₋ₓ₁₅N, in which 0<x14<1 and 0<x15<1. The composition of each element can be adjusted for different purposes, such as but not limited to tuning the bandgap. In addition, when the semiconductor device is a light-emitting device, the domain wavelength or the peak wavelength of the light-emitting device can also be adjusted accordingly.

The semiconductor devices in the present disclosure may be, such as light-emitting devices (e.g. LED and LD), light-absorbing devices (e.g. photodiode), or other non-light-emitting devices. The composition and dopant of each layer of the semiconductors devices in the present disclosure can be analyzed by any suitable methods, such as secondary ion mass spectrometer (SIMS). The thickness of each layer can also be determined by any appropriate technique, such as transmission electron microscope (TEM), or scanning electron microscope (SEM).

It should be understood by those skilled in the art that additional components may be added based on the embodiments described below. For example, unless otherwise specifies, descriptions “the first layer (or structure) is located on the second layer (or structure)” may include embodiments where the first layer (or structure) directly contacts with the second layer (or structure), as well as embodiments where other structures are located between the first layer (or structure) and the second layer (structure) such that they indirectly contact each other. In some embodiments, the relative positions (such as upper and lower positions) between the layers (or structures) may vary depending on the perspective.

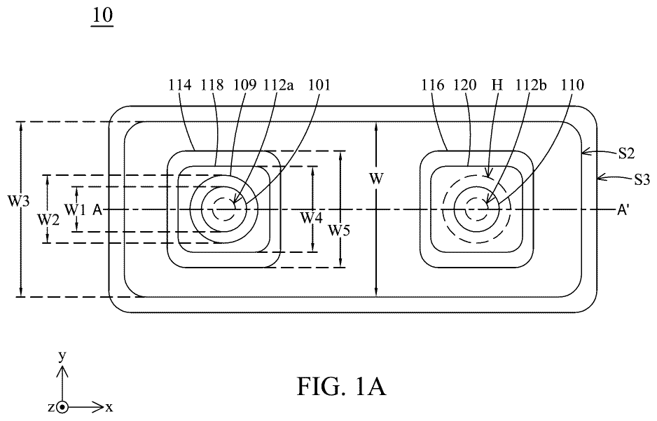

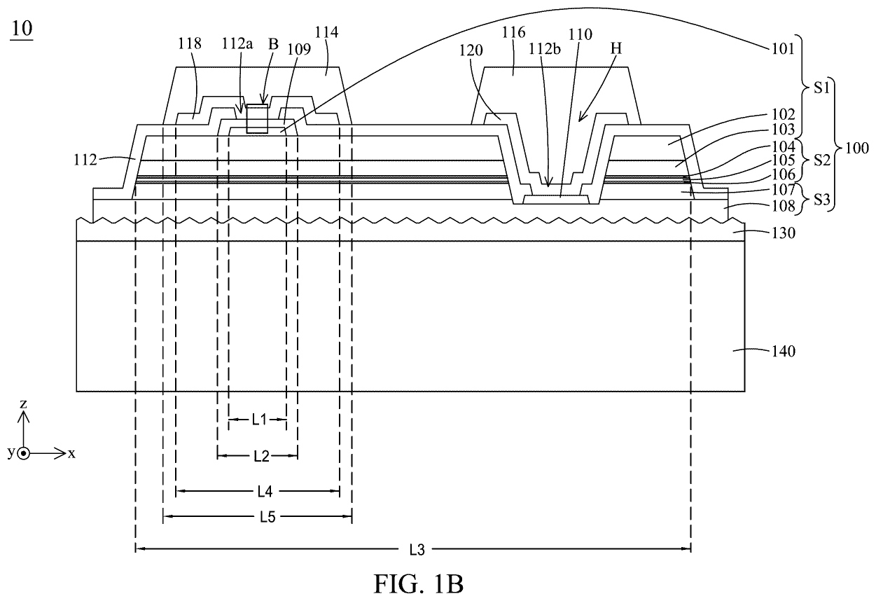

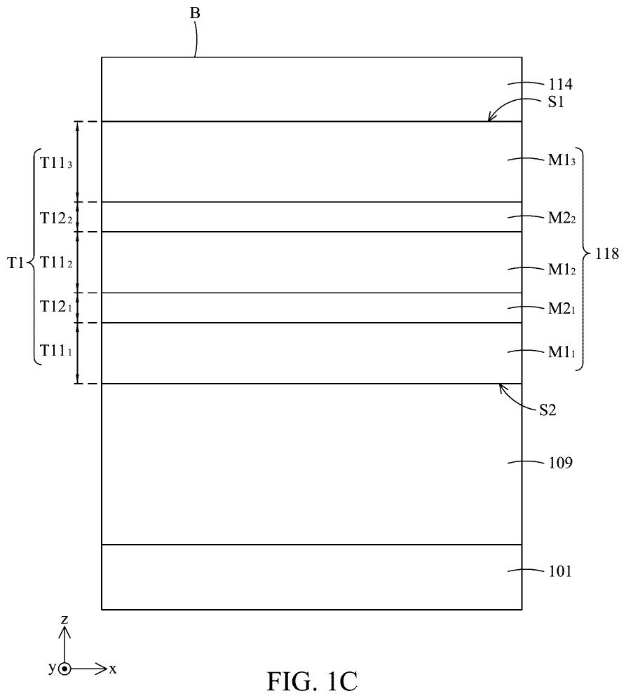

FIG. 1A shows a schematic top view of a semiconductor device 10 in accordance with some embodiments of the present disclosure; FIG. 1B shows a schematic sectional view of the semiconductor device 10 shown in FIG. 1A taken along line A-A′; and FIG. 1C shows a schematic enlarged view of the region B shown in FIG. 1B.

As shown in FIG. 1A and FIG. 1B, the semiconductor device 10 includes an epitaxial structure 100. The epitaxial structure 100 includes a first semiconductor structure S1, a second semiconductor structure S2, and an active structure S3 located between the first semiconductor structure S1 and the second semiconductor structure S2. The first semiconductor structure S1 and the second semiconductor structure S2 have different conductivity types respectively. When the semiconductor device 10 is a semiconductor light-emitting device, the first semiconductor structure S1 and the second semiconductor structure S2 can respectively provide electrons and holes (or holes and electrons) to the active structure S3. The electrons and holes can recombine within the active structure S3 to emit light of a specific wavelength. Specifically, the active structure S3 may include a double heterostructure (DH), a double-side double heterostructure (DDH), or a multiple quantum wells (MQW) structure. In some embodiments, when the semiconductor device 10 is a light-emitting device, the light emitted from the active structure S3 may be visible light or invisible light, and the wavelength of the emitted light is determined by the material of the active structure S3. For example, when the material of the active structure S3 includes AlGaN, the active structure S3 may emit ultraviolet (UV) light with a peak wavelength ranging from 250 nm to 300 nm; when the material of the active structure S3 includes InGaN, the active structure S3 may emit deep blue or blue light with a peak wavelength ranging from 400 nm to 490 nm, green or yellow light with a peak wavelength ranging from 490 nm to 550 nm, or red light with a peak wavelength ranging from 560 nm to 650 nm; when the material of the active structure S3 includes InGaP or AlGaInP, the active structure S3 may emit yellow, orange, or red light with a peak wavelength ranging from 530 nm to 700 nm; and when the material of the active structure S3 includes InGaAs, InGaAsP, AlGaAs, or AlGaInAs, the active structure S3 may emit red or infrared light with a peak wavelength ranging from 700 nm to 1700 nm.

The first semiconductor structure S1 may include a first cladding layer 103 and may selectively include a first semiconductor contact layer 101 and/or a first window layer 102. The active structure S3 may include a light-emitting layer 105 and may selectively include a first confinement layer 104 and a second confinement layer 106. The second semiconductor structure S2 may include a second cladding layer 107 and a second semiconductor contact layer 108. The total thickness of the epitaxial structure 100 may range from 0 μm to 10 μm (inclusive). In some embodiments, omitting the first window layer 102 can further reduce the total thickness of the epitaxial structure 100, which is beneficial for the miniaturization of the semiconductor device 10. The semiconductor device 10 may have a hole H formed in the epitaxial structure 100. As shown in FIG. 1A and FIG. 1B, the hole H extends from the first window layer 102 toward the second semiconductor contact layer 108 but does not penetrate through the entire epitaxial structure 100. As shown in FIG. 1B, a portion of the second semiconductor contact layer 108 is exposed.

In the epitaxial structure 100, the first semiconductor contact layer 101, the first window layer 102, and the first cladding layer 103 may have a first conductivity type, while the second cladding layer 107 and the second semiconductor contact layer 108 may have a second conductivity type different from the first conductivity type. In some embodiments, the first conductivity type is n-type, and the second conductivity type is p-type. In other embodiments, the first conductivity type is p-type, and the second conductivity type is n-type. The conductivity type of each layer can be adjusted by dopants. In some embodiments, the dopants may include Group II, Group IV, or Group VI elements from the periodic table, such as C, Zn, Si, Ge, Sn, Se, Mg, or Te. The first semiconductor contact layer 101, the first window layer 102, the first cladding layer 103, the first confinement layer 104, the light-emitting layer 105, the second confinement layer 106, the second cladding layer 107, and the second semiconductor contact layer 108 may include III-V semiconductor materials respectively. The III-V semiconductor materials may include Al, Ga, As, P, N, or In. In some embodiments, the III-V semiconductor materials may not include N. Specifically, the III-V semiconductor materials may be binary III-V semiconductor materials (e.g. GaAs, GaP, or GaN), ternary III-V semiconductor materials (e.g. InGaAs, AlGaAs, InGaP, AlInP, InGaN, or AlGaN), or quaternary III-V semiconductor materials (e.g. AlGaInAs, AlGaInP, AlInGaN, InGaAsP, InGaNAs, or AlGaAsP).

In some embodiments, the first semiconductor contact layer 101 includes a binary III-V semiconductor material, such as GaAs or GaP. In some embodiments, the first window layer 102 includes a ternary or quaternary III-V semiconductor material, such as InGaP, AlGaInP, or AlInP. In some embodiments, the first cladding layer 103 includes a ternary III-V semiconductor material, such as InGaP or AlInP. The first window layer 102 and the first cladding layer 103 may include different ternary III-V semiconductor materials. In some embodiments, the first confinement layer 104, the light-emitting layer 105, and the second confinement layer 106 includes ternary or quaternary III-V semiconductor materials, such as AlInP or AlGaInP. In some embodiments, the second cladding layer 107 includes a ternary III-V semiconductor material, such as InGaP or AlInP. In some embodiments, the second semiconductor contact layer 108 includes a binary III-V semiconductor material, such as GaAs or GaP.

In some embodiments, the semiconductor device 10 may selectively includes a first contact electrode 109, and the first contact electrode 109 is located on the first semiconductor structure S1. In some embodiments, the first contact electrode 109 directly contacts with the first semiconductor structure S1. As shown in FIG. 1B, the first contact electrode 109 directly contacts with the first semiconductor structure S1 to form an electrical connection. In some embodiments, the semiconductor device 10 may selectively include a second contact electrode 110, in which the second contact electrode 110 is located in the hole H and directly contacts with the second semiconductor structure S2. The second contact electrode 110 does not overlap with the first contact electrode 109 in the vertical direction (Z direction) so that the semiconductor device 10 has a horizontal structure. As shown in FIG. 1B, the second contact electrode 110 directly contacts with the second semiconductor structure S2 to form an electrical connection. In some embodiments, the top-view area of the first contact electrode 109 may be larger than, smaller than, or equal to the top-view area of the second contact electrode 110.

The materials of the first contact electrode 109 and the second contact electrode 110 may be the same or different, and may respectively include metals, alloys, or metal oxides. The materials of the first contact electrode 109 and the second contact electrode 110 may be respectively selected based on the materials of the first semiconductor contact layer 101 and the second semiconductor contact layer 108, so that the first contact electrode 109 and the second contact electrode 110 can respectively form a good electrical contact (e.g. ohmic contact) with the first semiconductor contact layer 101 and the second semiconductor contact layer 108. In some embodiments, the metals may be germanium (Ge), beryllium (Be), zinc (Zn), gold (Au), nickel (Ni), or copper (Cu). The alloys may include at least two members selected from the group consisting of the metals, such as GeAuNi, BeAu, GeAu, or ZnAu. The metal oxides may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), or indium zinc oxide (IZO). In some embodiments, the first contact electrode 109 includes GeAu, and the second contact electrode 110 includes BeAu. In other embodiments, the first contact electrode 109 includes BeAu, and the second contact electrode 110 includes GeAu.

As shown in FIG. 1B, in some embodiments, the semiconductor device 10 may selectively include an insulating structure 112. The insulating structure 112 can cover the epitaxial structure 100 to protect it from external environments or contaminants, thereby providing insulation to prevent electrical leakage. In some embodiments, the insulating structure 112 may be filled into the hole H and conformally cover the surface of the epitaxial structure 100 and/or the second contact electrode 110 to isolate the second contact electrode 110 from the active structure S3, thereby preventing the semiconductor device 10 from failing due to the electrical leakage caused by direct contact or proximity between the second contact electrode 110 and the active structure S3.

In some embodiments, the insulating structure 112 may have multiple separate openings. As shown in FIG. 1A and FIG. 1B, the insulating structure 112 has a first opening 112a and a second opening 112b, in which the positions of the first opening 112a and the second opening 112b respectively correspond to the positions of the first contact electrode 109 and the second contact electrode 110. In some embodiments, the top-view shapes of the first opening 112a and the second opening 112b of the insulating structure 112 may respectively be circular, elliptical, or polygonal. In some embodiments, the insulating structure 112 may include insulating materials with a single layer or multiple layers, in which the insulating materials may include oxides or nitrides, such as tantalum oxide (TaOₓ), aluminum oxide (AlOₓ), silicon oxide (SiOₓ), titanium oxide (TiOₓ), silicon nitride (SiNₓ), silicon oxynitride (SiOₓN_{y}), or niobium pentoxide (Nb₂O₅). In some embodiments, the insulating structure 112 may have a reflective function. For example, the insulating structure 112 may include a distributed Bragg reflector (DBR). In some embodiments, the DBR may include a plurality of first dielectric layers and a plurality of second dielectric layers (not shown) stacked alternately, and the plurality of first dielectric layers and the plurality of second dielectric layers have different refractive indices. In some embodiments, the plurality of first dielectric layers and the plurality of second dielectric layers may respectively include SiO₂, TiO₂, or Nb₂O₅. For example, the combination of the plurality of first dielectric layers and the plurality of second dielectric layers may be SiO₂/TiO₂ or SiO₂/Nb₂O₅. When the semiconductor device 10 is a light-emitting device and the light emitted from the active structure S3 needs to be emitted toward the direction of the second semiconductor contact layer 108, providing the insulating structure 112 with the reflective function can help reflect the light toward the direction of the second semiconductor contact layer 108, thereby increasing the light-emitting efficiency of the semiconductor device 10.

The semiconductor device 10 further includes a first pad 114 and may selectively include a second pad 116, in which the first pad 114 and the second pad 116 are respectively located on the first contact electrode 109 and the second contact electrode 110. In some embodiments, the first pad 114 and the second pad 116 are configured to electrically connect to external devices or external power sources. As shown in FIG. 1B, the first pad 114 and the second pad 116 are located on the insulating structure 112 and are physically separated from each other. The first pad 114 can electrically connect to the first contact electrode 109 through the first opening 112a, and the second pad 116 can electrically connect to the second contact electrode 110 through the second opening 112b. In some embodiments, the top-view area of the first pad 114 may be larger than, smaller than, or equal to the top-view area of the second pad 116.

In some embodiments, the first pad 114 and the second pad 116 may respectively have a structure with a single layer or multiple layers, and the materials of the first pad 114 and the second pad 116 may be the same or different and may include metal oxide materials or metals. In some embodiments, the metal oxide materials may include ITO, InO, SnO, CTO, ATO, AZO, ZTO, GZO, IWO, ZnO, or IZO, and the metals may be Au or Sn.

The semiconductor device 10 further includes a first barrier structure 118 located between the first contact electrode 109 and the first pad 114. As shown in FIG. 1B, the first barrier structure 118 can prevent the metal (e.g. Sn) in the first pad 114 from migrating toward the first contact electrode 109, thereby reducing the risk of structural defects between the first pad 114 and the first contact electrode 109 and improving the reliability of the semiconductor device 10. As shown in FIG. 1B, the first barrier structure 118 is located on the insulating structure 112 to be separated from the epitaxial structure 100, and the first barrier structure 118 is filled into the first opening 112a to directly contact the first contact electrode 109. In some embodiments, the first pad 114 is located on the first barrier structure 118 and forms an electrical connection with the first contact electrode 109 through the first barrier structure 118, and the position of the first barrier structure 118 corresponds to the position of the first contact electrode 109. In some embodiments, the first barrier structure 118 and the first pad 114 are completely overlapped in the vertical direction, and the top-surface of the first barrier structure 118 can be completely covered by the first pad 114 without being exposed.

In some embodiments, the first barrier structure 118 may be a structure with multiple layers. Referring to FIG. 1C, the first barrier structure 118 includes a first metal layer M1 and a second metal layer M2. In some embodiments, the first metal layer M1 and the second metal layer M2 respectively include a first metal and a second metal, and the first metal and the second metal are different metallic materials. In some embodiments, the first barrier structure 118 may include a plurality of first metal layers M1 and a plurality of second metal layers M2, and the plurality of first metal layers M1 and the plurality of second metal layers M2 are alternately stacked with each other along the vertical direction (Z direction). In some embodiments, the number of the plurality of first metal layers M1 may be larger than or equal to the number of the plurality of second metal layers M2. For example, the number of the plurality of first metal layers M1 and the number of the plurality of second metal layers M2 may be n and n−1 respectively, in which n is an integer between 2 and 5. For example, in the embodiment shown in FIG. 1C, the first barrier structure 118 includes a first metal layer M1₁, a second metal layer M2₁, a first metal layer M1₂, a second metal layer M2₂, and a first metal layer M1₃, which are sequentially stacked in the vertical direction. The first metal layer M1₁ and the first metal layer M1₃ may be respectively determined as a bottommost first metal layer and a topmost first metal layer, and the second metal layer M21 and the second metal layer M22 may be respectively determined as a bottommost second metal layer and a topmost second metal layer. In some embodiments, the plurality of second metal layers M2 are located between the bottommost first metal layer and the topmost first metal layer. In other words, both the first contact electrode 109 and the first pad 114 directly contacts with one of the plurality of first metal layers M1 of the first barrier structure 118 rather than with any of the plurality of second metal layer M2. Therefore, the bonding strength between the first contact electrode 109 and the first metal layer M11 or the bonding strength between the first metal layer M13 and the first pad 114 can be improved.

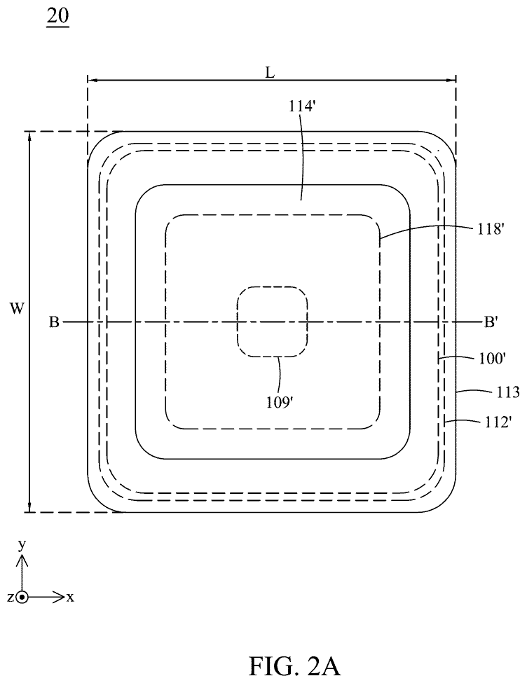

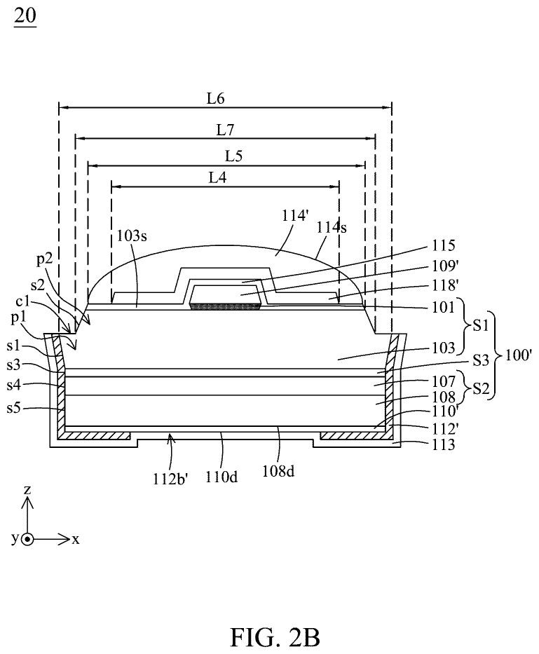

In some embodiments, the first pad 114 and/or the second pad 116 may be further irradiated with near-infrared (NIR) light to be heated and reshaped so that the sectional shape of their upper surfaces changes from a trapezoidal shape to an arc shape (shown in FIG. 2B), thereby reducing the probability of air voids being generated between the semiconductor device 10 and a carrier including an external device (or an external circuit) during subsequent connection. Therefore, the reliability of the semiconductor device 10 can be improved. In some embodiments, the wavelength of the NIR light may range from 950 nm to 1200 nm. For the NIR light irradiating the first pad 114 and the second pad 116, the first metal layer M1 has a first reflectivity, and the second metal layer M2 has a second reflectivity, in which the second reflectivity is larger than the first reflectivity. By providing the second metal layer M2 with a higher reflectivity, the reflection effect of the first barrier structure 118 on the NIR light can be improved. Therefore, the underlying first contact electrode 109 can be prevented from absorbing excessive NIR light and generating heat, which may further cause high temperature melting between the first contact electrode 109 and the first semiconductor contact layer 101. In some embodiments, the first reflectivity may be less than or equal to 80%, such as 70%, 60%, 50%, or 40%; the second reflectivity may be larger than or equal to 90%, such as 93%, 96%, or 99%. In some embodiments, the first metal layer M1 may include nickel (Ni), platinum (Pt), chromium (Cr), iron (Fe), beryllium (Be), or tungsten (W), and the second metal layer M2 may include aluminum (Al), silver (Ag), copper (Cu), or gold (Au). In some embodiments, the first metal layer M1 does not include Ti to avoid damage to the first metal layer M1 caused by laser processing or etching applied when transferring the semiconductor device 10 to another carrier, thereby preventing a reduction in the reliability of the semiconductor device 10.

As shown in FIG. 1C, the first barrier structure 118 has a first side E1 away from the epitaxial structure 100 and a second side E2 opposite the first side E1. In some embodiments, the metal (e.g. Sn) in the first pad 114 may migrate toward the first contact electrode 109 and enter the first barrier structure 118 after heating. Therefore, the concentration for the metal of the first pad 114 in the first barrier structure 118 decreases in a direction from the first side E1 to the second side E2. Specifically, the first metal layer M1₃ of the first barrier structure 118 directly contacts with the first pad 114, and the second metal layer M2₂ is located below the first metal layer M1₃ without contacting with the first pad 114. In some embodiments, the maximum concentration for the metal of the first pad 114 in the first metal layer M1₃ is larger than the maximum concentration thereof in the second metal layer M2₂.

In the vertical direction, the first barrier structure 118 has a total thickness T1. Each of the plurality of first metal layers M1 has a first thickness (T11ᵢ, in which i is 1 to n), and the first thicknesses T11 of the plurality of first metal layers M1 may be the same or different. Each of the plurality of second metal layers M2 has a second thickness (T12ᵢ, in which i is 1 to n−1), and the second thicknesses T12 of the plurality of second metal layers M2 may be the same or different. For example, in FIG. 1C, the first metal layer M1₁, the first metal layer M1₂, and the first metal layer M1₃ respectively have first thicknesses T11₁, T11₂, and T11₃, and the second metal layer M2₁ and the second metal layer M2₂ respectively have second thicknesses T12₁ and T12₂. In some embodiments, the second thickness T12 of each of the plurality of second metal layers M2 is smaller than the first thickness T11 of each of the plurality of first metal layers M1. In some embodiments, the total thickness T1 of the first barrier structure 118 may range from 0.5 μm to 4 μm, in which the first thicknesses (including T11₁ to T11ₙ) of the plurality of first metal layers M1 may range from 20 nm to 200 nm, and the second thicknesses (including T12₁ to T12ₙ₋₁) of the plurality of second metal layers M2 may range from 20 nm to 100 nm. When the first thickness T11 exceeds 200 nm, the first metal layer M1 may be at risk of cracking or peeling due to excessive stress. In some embodiments, the first thickness T11₃ of the first metal layer M1₃ (e.g. the topmost first metal layer) may be larger than the first thicknesses T11₁, T11₂ of the other first metal layers M1₁, M1₂ to enhance blocking of the migration of the metal from the first pad 114 toward the first contact electrode 109. In some embodiments, the total thickness T1 of the first barrier structure 118 may be larger than the total thickness of the first contact electrode 109.

As shown in FIG. 1A and FIG. 1B, in some embodiments, the semiconductor device 10 may further include a second barrier structure 120 located between the first contact electrode 110 and the second pad 116 to block the metal (e.g. Sn) of the second pad 116 from migrating toward the second contact electrode 110, thereby reducing the risk of structural defects between the second pad 116 and the second contact electrode 110. As shown in FIG. 1B, the second barrier structure 120 is located on the insulating structure 112 to be separated from the epitaxial structure 100, and the second barrier structure 120 is filled into the second opening 112b to directly contact the second contact electrode 110. In some embodiments, the second pad 116 is located on the second barrier structure 120 and forms an electrical connection with the second contact electrode 110 through the second barrier structure 120. Similarly, the position of the second barrier structure 120 corresponds to the position of the second contact electrode 110. In some embodiments, the second barrier structure 120 and the second pad 116 are completely overlapped in the vertical direction, and the top-surface of the second barrier structure 120 can be completely covered by the second pad 116 without being exposed. In some embodiments, the top-view area of the first barrier structure 118 may be larger than, smaller than, or equal to the top-view area of the second barrier structure 120. The material, structure, and function of the second barrier structure 120 are the same as those of the first barrier structure 118 and will not be repeated here.

In some embodiments, the semiconductor device 10 may selectively include a bonding structure 130 and/or a base 140 located below the epitaxial structure 100. As shown in FIG. 1A and FIG. 1B, the base 140 may be connected to the epitaxial structure 100 through the bonding structure 130. In some embodiments, the material of the bonding structure 130 may include oxide materials (e.g. SiO₂ or Al₂O₃), nitride materials (e.g. AlN or SiNₓ), or polymer materials (e.g. benzocyclobutene (BCB), epoxy, polyimide, or silicone). The bonding structure 130 may be a structure with a single layer or multiple layers. In some embodiments, the bonding structure 130 may include a main bonding layer and may selectively include a first auxiliary layer (not shown) located between the main bonding layer and the epitaxial structure 100 and/or a second auxiliary layer (not shown) located between the main bonding layer and the base 140. In some embodiments, the adhesion of the first auxiliary layer to the surface of the epitaxial structure 100 is larger than the adhesion of the main bonding layer to the surface of the epitaxial structure 100, and the adhesion of the second auxiliary layer to the surface of the base 140 is larger than the adhesion of the main bonding layer to the surface of the base 140. Therefore, providing the first auxiliary layer and the second auxiliary layer can further enhance both the bonding strength between the bonding structure 130 and the epitaxial structure 100 and the bonding strength between the bonding structure 130 and the base 140. In some embodiments, the thicknesses of the first auxiliary layer and the second auxiliary layer may both be smaller than the thickness of the main bonding layer. The main bonding layer may have a material different from that of the first auxiliary layer or the second auxiliary layer, and the first auxiliary layer and the second auxiliary layer may include the same material. For example, the first auxiliary layer and the second auxiliary layer may include an oxide material or a nitride material, and the main bonding layer may include a polymer material.

In some embodiments, the base 140 may include a conductive material or an insulating material. The conductive material may be, such as GaAs, InP, SiC, GaP, ZnO, GaN, AlN, Ge, or Si. The insulating material may be, such as sapphire or glass. In some embodiments, the base 140 may be a bonding substrate rather than a growth substrate, and the base 140 is bonded to the epitaxial structure 100 through the bonding structure 130. In other embodiments, the base 140 may be a growth substrate, in which the epitaxial structure 100 may be formed by, for example, metal-organic chemical vapor deposition (MOCVD), and no bonding structure 130 is provided between the base 140 and the epitaxial structure 100.

In some embodiments, the size of the semiconductor device 10 may be defined by the length and the width of the second semiconductor structure S2. As shown in FIG. 1A, in a top view, the second semiconductor structure S2 has a length L and a width W, in which the length L and the width W respectively correspond to the maximum length and the maximum width of the second semiconductor structure S2. In some embodiments, the length L and the width W may be smaller than or equal to 500 μm and larger than or equal to 1 μm, such as 450 μm, 400 μm, 350 μm, 300 μm, 250 μm, 200 μm, 150 μm, 100 μm, 50 μm, 30 μm, or 10 μm. In some embodiments, the top-view area (L ×W) of the semiconductor device 10 may be smaller than 25000 μm². For example, the top-view area of the semiconductor device 10 ranges from 1 μm² to 100 μm², 625 μm², 1250 μm², 2000 μm², 2500 μm², or 5000 μm². In some embodiments, in the top view, the semiconductor device 10 may have a rectangular or a square shape with rounded corners, and the diagonal length of the semiconductor device 10 may be larger than 1 μm and smaller than 700 μm.

As shown in FIG. 1A and FIG. 1B, the length L1 of the first semiconductor contact layer 101 may be smaller than or equal to the length L2 of the first contact electrode 109, and the length L2 of the first contact electrode 109 may be smaller than the length L3 of the active structure S3; the width W1 of the first semiconductor contact layer 101 may be smaller than or equal to the width W2 of the first contact electrode 109, and the width W2 of the first contact electrode 109 may be smaller than the width W3 of the active structure S3. In some embodiments, the top-view area of the first semiconductor contact layer 101 may be smaller than or equal to the top-view area of the first contact electrode 109 to avoid the material of the first semiconductor contact layer 101 from absorbing light emitted by the active structure S3. In some embodiments, the top-view area of the first contact electrode 109 is smaller than the top-view area of the active structure S3.

Continue to refer to FIG. 1A and FIG. 1B, in some embodiments, the length L4 of the first barrier structure 118 may be larger than the length L2 of the first contact electrode 109 and smaller than or equal to the length L5 of the first pad 114; the width W4 of the first barrier structure 118 may be larger than the width W2 of the first contact electrode 109 and smaller than or equal to the width W5 of the first pad 114. In some embodiments, the first barrier structure 118 may completely cover the first contact electrode 109 in the vertical direction, and the first pad 114 may also completely cover the surface of the first barrier structure 118. Therefore, the first barrier structure 118 is protected from being damaged by external environmental influences, thereby improving the reliability of the semiconductor device 10.

Similarly, in some embodiments, the length L1 and the width W1 are respectively corresponded to the maximum length and the maximum width of the first semiconductor contact layer 101; the length L2 and the width W2 are respectively corresponded to the maximum length and the maximum width of the first contact electrode 109; the length L3 and the width W3 are respectively corresponded to the maximum length and the maximum width of the active structure S3; the length L4 and the width W4 are respectively corresponded to the maximum length and the maximum width of the first barrier structure 118; and the length L5 and the width W5 are respectively corresponded to the maximum length and the maximum width of the first pad 114. In other words, in some embodiments, the length L3>the length L5≥the length L4>the length L2≥the length L1, and the width W3>the width W5≥the width W4>the width W2≥the width W1.

In some embodiments, the maximum thickness of the first semiconductor contact layer 101 may be smaller than 100 nm (e.g. larger than 1 nm and smaller than 20 nm, 30 nm, 40 nm, or 50 nm) to reduce the absorption of light emitted from the active structure S3 by the material of the first semiconductor contact layer 101. In some embodiments, the first semiconductor contact layer 101 may have a doping concentration larger than 5×10¹⁸ cm⁻³ (e.g. the doping concentration ranges from 6×10¹⁸ cm⁻³ to 1×10²⁰ cm⁻³) to provide the desired electrical conductivity.

In some embodiments, the top-view shape of the first semiconductor contact layer 101, the top-view shape of the first contact electrode 109, and the top-view shape of the second contact electrode 110 may respectively be a symmetrical pattern (e.g. a circle, a rectangle, or other geometrically symmetrical polygon), and the top-view shape of the first semiconductor contact layer 101 and the top-view shape of the first contact electrode 109 may be the same or different. In some embodiments, the top-view shape of the first contact electrode 109 is the same as the top-view shape of the first semiconductor contact layer 101 (e.g. both are circular with different radii only), and the top-view shapes of the first contact electrode 109 and the first semiconductor contact layer 101 are designed to be concentric. In other embodiments, the top-view shape of the first contact electrode 109 is different from the top-view shape of the first semiconductor contact layer 101. For example, the top-view shape of the first contact electrode 109 is a circle while the top-view shape of the first semiconductor contact layer 101 is a rectangle with rounded corners. Similarly, the top-view shape of the second contact electrode 110 and the top-view shape of the first contact electrode 109 may be the same or different. In some embodiments, the top-view shape of the first contact electrode 109 and/or the second contact electrode 110 may be designed to have a rounded-corner shape or to be circular to avoid excessive current concentration at sharp corners, thereby preventing from device failure.

In some embodiments, the top-view shapes of the first pad 114, the second, the first barrier structure 118, and the second barrier structure 120 may respectively be a symmetrical pattern, such as a circle, a rectangle, or other geometrically symmetrical polygon. The top-view shape of the first pad 114 and the top-view shape of the first barrier structure 118 may be the same, and the top-view shape of the first barrier structure 118 and the top-view shape of the first contact electrode 119 may be the same or different. In the vertical direction (Z direction), the geometric center of the first pad 114 and the geometric center of the first barrier structure 118 may be coincident or non-coincident, and the geometric center of the first barrier structure 118 and the geometric center of the first contact electrode 109 may be coincident or non-coincident. The relative relationship between the top-view shapes and the geometric centers of the second pad 116, the second barrier structure 120, and the second contact electrode 110 is the same as that of the first pad 114, the first barrier structure 118, and the first contact electrode 109, and will not be repeated here. Similarly, the top-view shape of the first pad 114, the second pad 116, the first barrier structure 118, and/or the second barrier structure 120 may be designed to have a rounded-corner shape or to be circular to avoid excessive current concentration at sharp corners, thereby preventing from device failure.

FIG. 2A shows a schematic top view of a semiconductor device 20 in accordance with other embodiments of the present disclosure, and FIG. 2B shows a schematic sectional view of the semiconductor device 20 shown in FIG. 2A taken along line B-B′. As shown in FIG. 2A and FIG. 2B, the semiconductor device 20 includes an epitaxial structure 100′, an insulating structure 112′, a first contact electrode 109′, a second contact electrode 110′, a first pad 114′, and a first barrier structure 118′, and the semiconductor device 20 does not include the second pad 116 and the second barrier structure 120 as included in the semiconductor device 10. In some embodiments, the first barrier structure 118′ has a fourth length L4, and the first pad 114′ has a fifth length L5.

Referring to FIG. 2B, the structure of the epitaxial structure 100′ is similar to that of the epitaxial structure 100, in which the first semiconductor structure S1 of the epitaxial structure 100′ does not have the first window layer 102, thereby further reducing the total thickness of the epitaxial structure 100′ to a range from 1 μm to 5 μm and facilitating miniaturization of the semiconductor device 20. Since the epitaxial structure 100′ does not have the hole H, the area of the active structure S3 can be maximized under the same size of the semiconductor device 10, thereby improving the brightness of the semiconductor device 20. In some embodiments, the first cladding layer 103 of the first semiconductor structure S1 may include a first portion p1 and a second portion p2. The first portion p1 is connected to the second portion p2 and closer to the active structure S3 than the second portion p2, and the first semiconductor contact layer 101 is located on the second portion p2. The first portion p1 has a sixth length L6, and the second portion p2 has a seventh length L7. In some embodiments, the sixth length L6 is the maximum length of the first portion p1, the seventh length L7 is the maximum length of the second portion p2, and the seventh length L7 may be smaller than or equal to the sixth length L6. In some embodiments, a mesa process may be performed on a portion of the first cladding layer 103 to form the second portion p2. In other embodiments, the mesa process may not be performed on the first cladding layer 103 so that the first cladding layer 103 may not have the second portion p2.

As shown in FIG. 2B, the first contact electrode 109′ of the semiconductor device 20 is located on the first semiconductor contact layer 101 and directly contacts with the first semiconductor contact layer 101 to form an electrical connection. The second contact electrode 110′ of the semiconductor device 20 is located below the second semiconductor contact layer 108 and directly contacts with the second semiconductor contact layer 108. Therefore, the semiconductor device 20 forms a vertical structure different from that of the semiconductor device 10, in which the second contact electrode 110′ may cover a portion or all of a lower surface 108d of the second semiconductor contact layer 108. In some embodiments, the material of the first contact electrode 109′ may be a metal, an alloy, or a metal oxide, the material of the second contact electrode 110′ may be a metal oxide, in which the second contact electrode 110′ may be transparent to light emitted from the active structure S3. Details regarding the metals, alloys, and metal oxides can be found in the description of the first contact electrode 109 and the second contact electrode 110 of the semiconductor device 10 and will not be repeated here.

As shown in FIG. 2B, the first pad 114′ of the semiconductor device 20 is located on the second portion p2 of the first cladding layer 103 and covers the first contact electrode 109′, and the first barrier structure 118′ is located between the first pad 114′ and the first contact electrode 109′. In other words, the first pad 114′ covers the first barrier structure 118′ (e.g. the sidewall of the first barrier structure 118′). Specifically, the first cladding layer 103 has an upper surface 103s, in which the first pad 114′ and the first barrier structure 118′ are located on the first cladding layer 103 and cover a portion or all of the upper surface 103s. When the first cladding layer 103 has the second portion p2, the upper surface 103s refers to the upper surface of the second portion p2. In some embodiments, the fifth length L5 of the first pad 114′ may be smaller than or equal to the seventh length L7 of the second portion p2, and the fourth length L4 of the first barrier structure 118′ may be smaller than or equal to the fifth length L5 of the first pad 114′ and/or the seventh length L7 of the second portion p2, thereby providing a sufficient bonding area for the first barrier structure 118′ and the first pad 114′ to increase adhesion. In some embodiments, the upper surface 114s of the first pad may be in an arc shape, which indicating that the first pad 114′ has been heated and reshaped by the NIR. Details regarding the materials, structures, and functions of the first pad 114′ and the first barrier structure 118′ can be found in the description of the first pad 114 and the first barrier structure 118 of the semiconductor device 10 and will not be repeated here.

In some embodiments, the semiconductor device 20 may selectively include a conductive layer 115, in which the conductive layer 115 is located between the first contact electrode 109′ and the first barrier structure 118′. As shown in FIG. 2B, the conductive layer may cover the surface of the first contact electrode 109′ and a portion or all of the upper surface 103s of the first cladding layer 103 to improve current conduction in the horizontal direction and enhance lighting uniformity. In some embodiments, the width of the conductive layer 115 may be smaller than or equal to the width W7 of the second portion p2. In some embodiments, the conductive layer 115 may serve as a contact layer located between the first contact electrode 109′ and the first cladding layer 103 to replace the first semiconductor contact layer 101 (not shown). In some embodiments, the conductive layer 115 may include a conductive material, such as a metal oxide (e.g. ITO, InO, SnO, CTO, ATO, AZO, ZTO, GZO, IWO, ZnO, or IZO).

As shown in FIG. 2B, the insulating structure 112′ of the semiconductor device 20 covers a portion of the surface of the epitaxial structure 100′ and a portion of the surface of the second contact electrode 110′. In some embodiments, the insulating structure 112′ does not cover the upper surface 103s of the first cladding layer 103 and does not contact the first contact electrode 109′ and the first barrier structure 118′. Therefore, the insulating structure 112′ has only a second opening 112b′ corresponding to the second contact electrode 110′ and does not have a first opening corresponding to the first contact electrode 109′. Specifically, in some embodiments, the first portion p1 and the second portion p2 of the first cladding layer 103 respectively have a first side surface s1 and a second side surface s2, the active structure S3 has a third side surface s3, the second cladding layer 107 has a fourth side surface s4, and the second semiconductor contact layer 108 has a fifth side surface s5. In some embodiments, the first portion p1 may selectively have a connecting surface c1 located between the first side surface s1 and the second side surface s2, thereby connecting the first side surface s1 and the second side surface s2. As shown in FIG. 2B, the insulating structure 112′ continuously covers the first side surface s1, the third side surface s3, the fourth side surface s4, and the fifth side surface s5 and extends to cover a portion of the lower surface 108d of the second semiconductor contact layer 108 and/or a portion of the lower surface 110d of the second contact electrode 110′. In some embodiments, the insulating structure 112′ does not cover the second side surface s2 and the connecting surface c1.

In some embodiments, the insulating structure 112′ of the semiconductor device 20 is similar to the insulating structure 112 of the semiconductor device 10, in which the insulating structure 112′ may include insulating materials with a single layer or multiple layers and have a reflective function. When the semiconductor device 20 is a light-emitting device, the insulating structure 112′ can reflect the light emitted from the active structure S3 toward the direction of the second semiconductor contact layer 108, and the light is emitted through the second contact electrode 110′. In some embodiments, the insulating structure 112′ further covers the second side surface s2 and the connecting surface c1 of the first cladding layer 103 (not shown) to increase reflective area, thereby increasing the light-emitting efficiency of the semiconductor device 20. Details regarding the material and function of the insulating structure 112′ can be found in the description of the insulating structure 112 of the semiconductor device 10 and will not be repeated here.

In some embodiments, the semiconductor device 20 may selectively include a blocking layer 113. As shown in FIG. 2A and FIG. 2B, the blocking layer 113 may cover a portion or all of the insulating structure 112′ and may serve as an etching-blocking layer. In some embodiments, the insulating structure 112′ is located between the blocking layer 113 and the epitaxial structure 100′ and directly contacts with the blocking layer 113. Therefore, when it is necessary to perform process (e.g. laser process or etching process) on the semiconductor device 20 for transferring the semiconductor device 20, the blocking layer 113 can further protect the insulating structure 112′ and the epitaxial structure 100′ to prevent their structures from being damaged. In some embodiments, the blocking layer 113 may be a structure with a single layer or multiple layers, and the material of the insulating structure 112′ may be different from the material of the blocking layer 113. For example, in some embodiments, the blocking layer 113 has better etching resistance than the insulating structure 112′ for fluorine-including gases, such as carbon tetrafluoride (CF₄).

In some embodiments, the blocking layer may cover the insulating structure 112′ distributed at different locations. As shown in FIG. 2B, the insulating structure distributed at the lower surface 110d, the fifth side surface s5, the fourth side surface s4, the third side surface, and/or the first side surface s1 may be covered by the blocking layer 113. In some embodiments, the blocking layer 113 continuously covers the insulating structure 112′. As shown in FIG. 2B, the blocking layer 113 may be filled into the second opening 112b′ and directly contacts with the second contact electrode 110′. In some embodiments, one side of the blocking layer 113 directly contacts with the second contact electrode 110′, and the other side of the blocking layer 113 directly contacts an external conductive structure (not shown) to form an electrical connection with an external power supply or device.

In some embodiments, the thickness of the blocking layer 113 ranges from 1000 Å to 3000 Å. In some embodiments, the material of the blocking layer 113 may be a conductive material or an insulating material and may be transparent to light emitted from the active structure S3. When the material of the blocking layer 113 is conductive, the blocking layer 113 can simultaneously provide protection and conductivity and prevent electrostatic discharge during device fabrication, thereby improving process stability. In some embodiments, the conductive materials may include a metal oxide, such as ITO, InO, SnO, CTO, ATO, AZO, ZTO, GZO, IWO, ZnO, or IZO. In some embodiments, the second contact electrode 110′ and the blocking layer 113 may include the same materials, thereby providing a better adhesion between the second contact electrode 110′ and the blocking layer 113 to prevent the blocking layer 113 from easily peeling off. For example, the material of the second contact electrode 110′ and the material of the blocking layer 113 may both include a metal oxide, such as ITO. In some embodiments, the blocking layer 113 and the conductive layer 115 may include the same material.

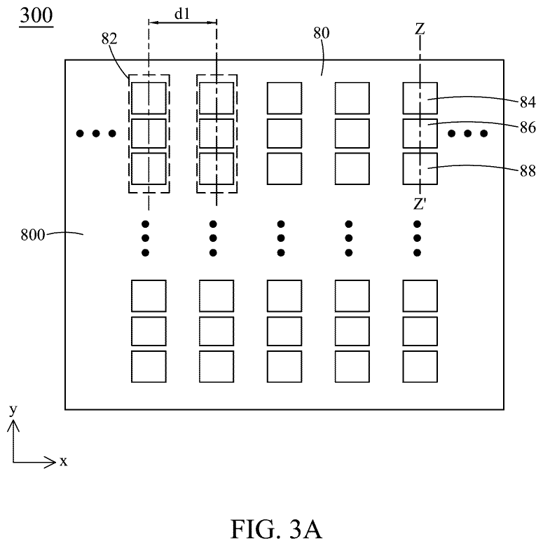

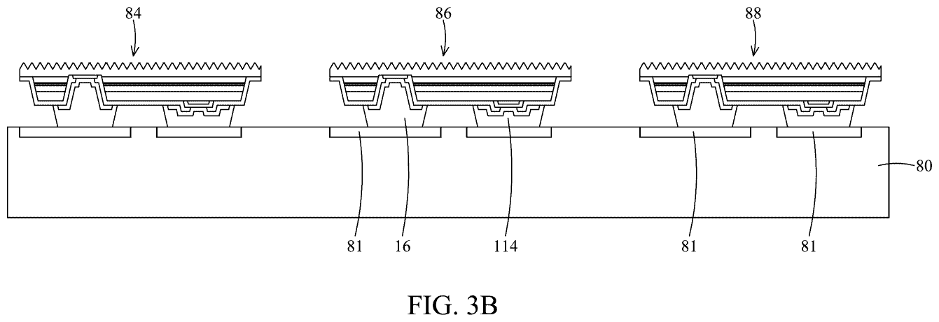

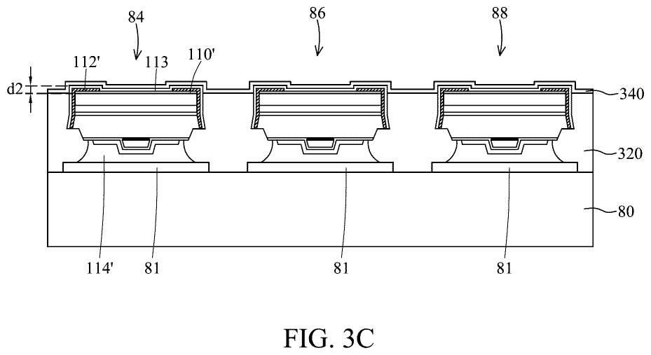

FIG. 3A shows a schematic top view of a display in accordance with some embodiments of the present disclosure. As shown in FIG. 3A, a display 300 may include a target carrier 80 and a plurality of pixel units 82 located on the target carrier 80. The plurality of pixel units 82 are arranged in an array along directions parallel to the x-axis and the y-axis and are arranged in the direction parallel to the x-axis with a spacing d1. The target carrier 80 may have a structure with a single layer or multiple layers. The target carrier 80 may be a printed circuit board (PCB) or a thin-film transistor (TFT) substrate. The material of the target carrier 80 may include polyester, polyimide (PI), bismaleimide triazine, polytetrafluoroethylene, phenol (PF), or glass fiber reinforced epoxy (FR4). The number of the plurality of pixel units 82 may be adjusted as needed. For example, in some embodiments, the plurality of pixel units 82 included in the display 300 may provide a resolution of 1920×1080 pixels. In some embodiments, the spacing d1 may be smaller than 1.4 mm. For example, the spacing d1 ranges from 0.2 mm to 1.3 mm; specifically, the spacing d1 may be 0.75 mm, 0.8 mm, 1 mm, or 1.25 mm. As shown in FIG. 3A, each of the plurality of pixel units 82 includes a first semiconductor device 84, a second semiconductor device 86, and a third semiconductor device 88 arranged along the direction parallel to the y-axis. Specifically, one or more of the first semiconductor device 84, the second semiconductor device 86, and the third semiconductor device 88 may be the semiconductor device as described in the embodiments (e.g., the semiconductor device 10 or 20). In some embodiments, the first semiconductor device 84, the second semiconductor device 86, and the third semiconductor device 88 are all light-emitting devices and emit different light. The first semiconductor device 84, the second semiconductor device 86, and the third semiconductor device 88 can emit red light, green light, or blue light. In some embodiments, the arrangement order of these light-emitting devices may also be adjusted as needed. For example, the first semiconductor device 84 may emit red light, the second semiconductor device 86 may emit blue light, and the third semiconductor device 88 may emit green light. Each of the plurality of pixel units 82 may be electrically connected to a circuit (not shown) on the surface of the target carrier 80 so that the semiconductor devices therein can receive external signals and emit light according to the external signals. In some embodiments, the target carrier 80 is bendable and able to withstand a state that its curvature radius is smaller than 50 mm (e.g. 25 mm or 32 mm).

FIG. 3B shows a schematic sectional view of the display 300 in accordance with some embodiments of the present disclosure taken along line Z-Z′ shown in FIG. 3A. In some embodiments, the first semiconductor device 84, the second semiconductor device 86, and the third semiconductor device 88 of each of the plurality of pixel units 82 are shown using the structure of the semiconductor device 10 as an example. As shown in FIG. 3B, the target carrier may include a plurality of electrical connection structures 81 for connecting a plurality of semiconductor devices. Specifically, the first semiconductor device 84, the second semiconductor device 86, and the third semiconductor device 88 may be mounted on the target carrier 80 in a flip-chip manner, and the first semiconductor device 84, the second semiconductor device 86, and the third semiconductor device 88 are respectively soldered and fixed on the corresponding electrical connection structure 81 through the first pad 114 and the second pad 116. Each of the plurality of electrical connection structures 81 include a conductive material, such as a metal or an alloy. The positions, relative relationships, material compositions, and variations of other layers or structures in the present embodiment have been described in detail in the embodiments and will not be repeated here.

FIG. 3C shows a schematic sectional view of the display 300 in accordance with other embodiments of the present disclosure taken along line Z-Z′ shown in FIG. 3A. In some embodiments, the first semiconductor device 84, the second semiconductor device 86, and the third semiconductor device 88 of each of the plurality of pixel units 82 are shown using the structure of the semiconductor device 20 as an example. As shown in FIG. 3C, the target carrier may include a plurality of electrical connection structures 81. The first semiconductor device 84, the second semiconductor device 86, and the third semiconductor device 88 are respectively soldered and fixed on the corresponding electrical connection structure 81 through the first pad 114′, thereby being fixed on the target carrier 80. In some embodiments, the display 300 further includes a dielectric structure 320. The dielectric structure 320 covers the target carrier 80 and covers side surfaces of the first semiconductor device 84, the second semiconductor device 86, and the third semiconductor device 88. As shown in FIG. 3C, the dielectric structure 320 is filled in spaces between the first semiconductor device 84, the second semiconductor device 86, and the third semiconductor device 88. The dielectric structure 320 may include an opaque material or a reflective material. In some embodiments, the dielectric structure 320 may include a matrix and a black material. The matrix may include silicone, epoxy, or a mixture thereof. The black material may include carbon black.

In some embodiments, the display 300 further includes a conductive line 340. As shown in FIG. 3C, the conductive line may cover the dielectric structure 320, the first semiconductor device 84, the second semiconductor device 86, and the third semiconductor device 88 and be electrically connected to the first semiconductor device 84, the second semiconductor device 86, and the third semiconductor device 88. The conductive line 340 may conformally cover the dielectric structure 320. As shown in FIG. 3C, in some embodiments, the conductive line 340 may directly contact the blocking layer 113 of each semiconductor device to form an electrical connection. In other embodiments, when the first semiconductor device 84, the second semiconductor device 86, and the third semiconductor device 88 do not have the blocking layer, the conductive line 340 may directly contact the second contact electrode 110′ to form an electrical connection. As shown in FIG. 3C, there is a vertical distance d2 between the upper edge of the dielectric structure 320 and the upper edge of the first semiconductor device 84, the second semiconductor device 86, and/or the third semiconductor device 88. In some embodiments, the vertical distance d2 may be smaller than or equal to ½ or ⅓ of the thickness of the first semiconductor device 84, the second semiconductor device 86, or the third semiconductor device 88, thereby preventing the conductive line 340 from breaking due to an excessively large vertical distance. In some embodiments, the conductive line 340 may include a transparent and conductive material, such as a metal oxide, a metal, or an alloy. The metal oxide may be, such as ITO, InO, SnO, CTO, ATO, AZO, ZTO, GZO, IWO, ZnO, or IZO. The metal may be, such as Au, Pt, Ti, Al, Cu, or Ni. include at least two members selected from the group consisting of the metals, such as GeAuNi, BeAu, GeAu, or ZnAu. In some embodiments, the conductive line 340 and the block layer 113 may include the same material, thereby providing a better adhesion between the conductive line 340 and the block layer 113 to improve the structural stability of the display 300. The positions, relative relationships, material compositions, and variations of other layers or structures in the present embodiment have been described in detail in the embodiments and will not be repeated here.

In conclusion, according to one or some embodiments of the present disclosure, a semiconductor device, a semiconductor assembly including the same, a display, and a manufacturing method thereof are provided to improve characteristics of the device, such as current spreading or light extraction efficiency of the device. Specifically, the semiconductor devices and the semiconductor assemblies of the present disclosure can be applied to products in fields of lighting, display, communication, and power systems. For example, the products may be lamps, monitors, automotive dashboards, televisions, computers, traffic signals, and outdoor displays.

Although the present disclosure has been described in considerable detail with reference to certain embodiments thereof, the disclosure is not for limiting the scope of the invention. Persons having ordinary skill in the art may make various modifications and changes without departing from the scope and spirit of the disclosure. Therefore, the scope of protection of the present disclosure shall be defined by the appended claims.

What is claimed is:

1. A semiconductor device, comprising:
an epitaxial structure comprising a first semiconductor structure, a second semiconductor structure, and an active structure located between the first semiconductor structure and the second semiconductor structure;
a first pad located on the second semiconductor structure;
a first contact electrode located between the second semiconductor structure and the first pad; and
a first barrier structure located between the first contact electrode and the first pad, the first barrier structure comprising a first metal layer and a second metal layer;
wherein, the first metal layer has a first reflectivity for a light with a wavelength ranging from 950 nm to 1200 nm, the second metal layer has a second reflectivity for the light with the wavelength ranging from 950 nm to 1200 nm, and the second reflectivity is larger than the first reflectivity;
the first metal layer comprises a first thickness, the second metal layer comprises a second thickness, and the first thickness is larger than the second thickness.

2. The semiconductor device according to claim 1, wherein the first barrier structure comprises a plurality of first metal layers and a plurality of second metal layers, and the plurality of first metal layers and the plurality of second metal layers are alternately stacked with each other.

3. The semiconductor device according to claim 2, wherein the plurality of first metal layers comprises a topmost first metal layer and a bottommost first metal layer, and the plurality of second metal layers are located between the topmost first metal layer and the bottommost first metal layer.

4. The semiconductor device according to claim 3, wherein each of the plurality of first metal layers comprises a thickness and the thickness of the topmost first metal layer is larger than the thicknesses of the others of the plurality of first metal layers.

5. The semiconductor device according to claim 2, wherein each of the plurality of first metal layers comprises a first thickness and each of the plurality of second metal layers comprises a second thickness, and the first thickness is larger than the second thickness.

6. The semiconductor device according to claim 2, wherein the first metal layer comprises nickel (Ni), platinum (Pt), chromium (Cr), iron (Fe), beryllium (Be), or tungsten (W), and the second metal layer comprises aluminum (Al), silver (Ag), copper (Cu), or gold (Au).

7. The semiconductor device according to claim 1, wherein the thickness of the first metal layer ranges from 20 nm to 200 nm.

8. The semiconductor device according to claim 1, wherein the thickness of the second metal layer ranges from 20 nm to 100 nm.

9. The semiconductor device according to claim 1, wherein the first barrier structure has a first sidewall, and the first pad covers the first sidewall.

10. The semiconductor device according to claim 1, further comprising:
an insulating structure located between the epitaxial structure and the first barrier structure.

11. The semiconductor device according to claim 10, wherein the insulating structure comprises a first opening corresponding to the first contact electrode, and the first barrier structure covers the first opening and the first contact electrode.

12. The semiconductor device according to claim 1, wherein the first barrier structure has a first side away from the epitaxial structure and a second side opposite the first side, the first pad comprises a metal with a concentration, and the concentration of the metal in the first barrier structure decreases in a direction from the first side to the second side.

13. The semiconductor device according to claim 1, wherein, in a sectional view, the first pad comprises an upper surface of an arc shape.

14. The semiconductor device according to claim 1, wherein the first metal layer does not comprise Ti.

15. The semiconductor device according to claim 1, wherein the first metal layer directly contacts the first pad.

16. The semiconductor device according to claim 1, wherein the first barrier structure comprises a total thickness larger than a thickness of the first contact electrode.

17. The semiconductor device according to claim 1, wherein the first barrier structure completely covers the first contact electrode in a vertical direction.

18. The semiconductor device according to claim 1, wherein the first pad completely covers the first barrier structure in the vertical direction.

19. A display comprising:
a carrier; and
a first semiconductor device of claim 1 disposed on the carrier.

20. The display according to claim 19, further comprising:
a second semiconductor device disposed on the carrier; and
a third semiconductor device disposed on the carrier;
wherein the first semiconductor device, the second semiconductor device and the third semiconductor device emit different light.
